(19) United States
(12) Patent Application Publication
(10) Pub. No.: US 2026/0005687 A1
(43) Pub. Date: Jan. 1, 2026

(54) CIRCUIT UNIT, CIRCUIT ARRANGEMENT AND METHOD FOR REDUCING SWITCHING LOSSES OF A SEMICONDUCTOR SWITCH

(71) Applicant: Robert Bosch GmbH, Stuttgart (DE)

(72) Inventors: Christoph Henrik van der Broeck, München (DE); Klaas Strempel, Stuttgart (DE); Hauke Van Hoek, Renningen (DE)

(21) Appl. No.: 19/215,828

(22) Filed: May 22, 2025

(30) Foreign Application Priority Data
May 27, 2024 (DE) 10 2024 204 845.3

(51) Int. Cl. H03K 17/082; H02M 1/00

(52) U.S. Cl. CPC H03K 17/082; H02M 1/0058; H03K 2217/0027

(57) ABSTRACT

A circuit unit for reducing switching losses of a semiconductor switch. The circuit unit includes: the semiconductor switch, an auxiliary switch, a capacitor, and a logic unit. A series circuit including the auxiliary switch and the capacitor is connected in parallel with a load path of the semiconductor switch. The logic unit is configured to determine, in a switched-on state of the semiconductor switch, a current intensity of an electric current to be switched using the semiconductor switch and flowing along the load path, close the auxiliary switch or to keep it in a closed state before a switch-off operation of the semiconductor switch when the determined current intensity exceeds a predefined current threshold value, and open the auxiliary switch or to keep it in an open state before a switch-off operation of the semiconductor switch when the determined current intensity does not exceed the predefined current threshold value.

### FIELD

The present invention relates to a circuit unit, a circuit arrangement and a method for reducing switching losses of a semiconductor switch.

### BACKGROUND INFORMATION

The related art describes zero volt switching (ZVS) methods, which reduce switching losses by switching on semiconductor switches whenever a voltage present at the semiconductor switches substantially corresponds to a value of zero.

Furthermore, it is described in the related art that, by connecting an external capacitance in parallel with a semiconductor switch, switching losses can be reduced by the semiconductor switch when high currents are to be switched. In addition, a du/dt of the semiconductor switch can be reduced in this way, which improves the electromagnetic compatibility (EMC) of a circuit comprising the semiconductor switch(es).

### SUMMARY

According to a first aspect of the present invention, a circuit unit for reducing switching losses of a semiconductor switch is provided. According to an example embodiment of the present invention, the circuit unit comprises such a semiconductor switch, an auxiliary switch, a capacitor (which may be a single capacitor or may be composed of a plurality of capacitors connected in parallel), and a logic unit.

The semiconductor switch is designed, for example, as a single semiconductor switch or as a parallel circuit consisting of a plurality of semiconductor switches. Since the semiconductor switch is the actual switch for blocking or conducting a load current, this semiconductor switch may also be regarded as the main switch of the circuit unit.

The capacitor corresponds to a capacitor connected externally to the semiconductor switch and does not represent the internal capacitance of the semiconductor switch.

A series circuit consisting of the auxiliary switch and the capacitor is connected in parallel with a load path of the semiconductor switch. This explicitly does not exclude the possibility that further electrical components, such as a damping resistor, may be connected in parallel and/or in series with the capacitor.

According to an example embodiment of the present invention, the logic unit, which may be designed as an integrated and/or discrete logic circuit, is configured to determine, in a switched-on state of the semiconductor switch, a current intensity of an electric current to be switched by means of the semiconductor switch and flowing along the load path of the semiconductor switch. The determination may be carried out, for example, on the basis of a measurement and/or an estimate of the current to be switched by means of the semiconductor switch.

The logic unit may also be a subunit of a control unit and/or of a driver unit, which is provided for controlling the semiconductor switch.

According to an example embodiment of the present invention, the logic unit is further configured to close the auxiliary switch or to keep it in a closed state before a switch-off operation of the semiconductor switch if the determined current intensity exceeds a predefined current threshold value. The logic unit is also configured according to the present invention to open the auxiliary switch or to keep it in an open state before a switch-off operation of the semiconductor switch if the determined current intensity does not exceed the predefined current threshold value.

Depending on the configuration of the auxiliary switch and/or a configuration of the logic unit, it may be useful or necessary for the auxiliary switch to be controlled via a driver unit, connected between the logic unit and the auxiliary switch, for the auxiliary switch, which driver unit converts respective control signals provided by the logic unit for switching the auxiliary switch on and off into suitable control signals for the auxiliary switch.

A capacitance value of the capacitor and the current threshold value are advantageously specified depending on an expected range of a current to be switched by means of the semiconductor switch, so that the lowest possible total losses of the circuit unit can be achieved when switching both high and low currents.

In an exemplary case, in which the circuit unit is used, for example, in a bidirectional charger in which a first current and a second current, which is higher than the first current, are to be switched at different times by means of the circuit unit, the capacitance value of the capacitor and the current threshold value can be designed accordingly advantageously with regard to these expected currents.

Furthermore, the circuit unit according to the present invention can be used in numerous other applications, for example in switch-mode power supplies and other applications differing therefrom.

It should be noted in general that the current threshold value can be designed as an invariable or as a more adjustable current threshold value; the current threshold value in the latter case can, for example, be adjusted in a suitable manner depending on present boundary conditions such as changing currents to be switched, etc.

The present invention offers the advantage that low switching losses can be achieved across a wide operating range. In particular, in connection with zero voltage switching (or quasi-zero voltage switching, in which a certain residual voltage is present at the semiconductor switch before a switching operation), the switching losses can be kept low, while switching off the external capacitance at low currents (i.e., currents that are below the current threshold value) makes zero voltage (or quasi-zero voltage) switching possible even at these low currents.

Preferred developments of the present invention are disclosed herein.

In a preferred example embodiment of the present invention, the semiconductor switch is designed as a power transistor and/or as a Si-, SiC-, or GaN-based semiconductor switch and/or as a MOSFET, HEMT, IGBT, JFET, FinFET, CAVET, or as a bipolar transistor. Further preferably, the auxiliary switch is also designed as a semiconductor switch (e.g., in the form of one of the aforementioned types) and/or as an electromechanical switch.

A specific type of the auxiliary switch is preferably specified depending on a required switching frequency and/or a permissible space requirement and/or permissible costs and/or a required current-carrying capacity and/or voltage rating of the auxiliary switch.

In a further advantageous example embodiment of the present invention, the current threshold value is an upper threshold value of a hysteresis, and the logic unit is configured to switch the auxiliary switch from a closed state to an open state only if the value falls below a lower current threshold value of the hysteresis, which is smaller than the upper current threshold value. Such a hysteresis can be used particularly advantageously if the assumption can be made that non-monotonically rising and/or falling currents are to be switched by means of the semiconductor switch in order to avoid undesired switching back and forth between the state with the capacitor switched on and the state with the capacitor not switched on at currents that are in the range of the current threshold value. This makes it possible, among other things, to reduce instabilities in a higher-level circuit using the circuit unit and/or to reduce switching losses. A use of such a hysteresis may, for example, be particularly advantageous if the circuit unit according to the present invention is used as a component of a dual active bridge, of a resonant converter, or of an application differing therefrom with similar load current profiles. Alternatively or additionally, the circuit unit is configured to determine the current intensity of the current to be switched by means of the semiconductor switch, substantially immediately before the start of a switch-off operation of the semiconductor switch, whereby, for example in connection with the aforementioned non-monotonically rising and/or falling currents that are to be switched by means of the semiconductor switch, undesired switching back and forth between the states with the capacitor switched on and not switched on can also be reduced or avoided.

Particularly advantageously, according to an example embodiment of the present invention, the capacitor is a first capacitor and the circuit unit has at least a second capacitor. Depending on the requirements for the circuit unit according to the present invention and/or for existing boundary conditions, it is possible for a capacitance value of the second capacitor to be specified identically to the first capacitor or differently to the first capacitor. In addition, the auxiliary switch is a first auxiliary switch and the circuit unit has at least a second auxiliary switch. Furthermore, the current threshold value corresponds to a first current threshold value. A series circuit consisting of the second auxiliary switch and the second capacitor is connected in parallel with the load path of the semiconductor switch. On this basis, the logic unit is configured to close the second auxiliary switch or to keep it in a closed state before a switch-off operation of the semiconductor switch if the determined current intensity exceeds a second predefined current threshold value, which is greater than the first current threshold value. The logic unit is further configured to open the second auxiliary switch or to keep it in an open state before a switch-off operation of the semiconductor switch if the determined current intensity does not exceed the second predefined current threshold value. In this way, a magnitude of a capacitance connected in parallel with the semiconductor switch can be adapted more precisely to a currently present current to be switched. In other words, the second auxiliary switch and the second capacitor offer the possibility of providing an additional gradation of the parallel-connected capacitance, which can further reduce switching losses, in particular when the currents to be switched vary. In this way, it is particularly advantageously possible to provide further auxiliary switches and further capacitors corresponding to the auxiliary switches, in order to achieve even finer gradations or adaptability to present currents to be switched. It should be noted that the logic unit may also be composed of a plurality of logic units, each of which may be intended to control one or more auxiliary switches.

Furthermore, the circuit unit is advantageously configured to determine the current intensity of the current to be switched by means of the semiconductor switch, on the basis of a current measurement within the semiconductor switch (e.g., on the basis of a measuring shunt) and/or a voltage measurement across the load path of the semiconductor switch and/or information provided from outside (e.g., from a higher-level unit which adjusts and/or monitors a current to be presently switched, etc.) and/or an operating state of the circuit unit and/or an operating state of a higher-level circuit arrangement containing the circuit unit.

Particularly preferably, according to an example embodiment of the present invention, the semiconductor switch and/or the auxiliary switch and/or the capacitor and/or the logic unit are integrated, in particular partially or completely monolithically integrated. For this purpose, the aforementioned components or a portion of the aforementioned components are, for example, each formed on separate chips, which form a module, and/or on individual chips. Alternatively or additionally, a measuring unit for determining the current intensity of the current to be switched (which, for example, measures a current and/or a voltage and/or a temperature on the basis of which the current to be switched can be derived) and/or a first driver circuit for controlling the semiconductor switch and/or a second driver circuit for controlling the auxiliary switch are integrated with the circuit unit, in particular partially or completely monolithically integrated with the circuit unit.

In a further advantageous example embodiment of the present invention, at least the semiconductor switch and the auxiliary switch are formed on substrates which are electrically isolated from one another. Alternatively or additionally, the capacitor is connected with low inductance to the circuit unit so that the capacitance of the capacitor can be effective in a relevant frequency range without being affected by the influence of a connection with an excessively high inductance. This is in particular advantageous if the capacitor is designed as a discrete component, which is electrically connected to the semiconductor switch and/or the auxiliary switch, for example via bonding wires.

According to a second aspect of the present invention, a circuit arrangement comprising at least one circuit unit according to the first aspect of the present invention and a control unit is provided, wherein the control unit is configured to switch on the semiconductor switch of the at least one circuit unit substantially without voltage. The features, combinations of features and the advantages resulting therefrom correspond to those discussed in connection with the first-mentioned aspect of the present invention, such that reference is made to the above statements in order to avoid repetitions.

In an advantageous example embodiment of the circuit arrangement according to the present invention, the circuit arrangement is configured to determine a switch-on loss of the semiconductor switch on the basis of a present and/or an intended switching state of the auxiliary switch and to adjust the auxiliary switch in accordance with the determined current intensity when switching off the semiconductor switch, only if a predefined maximum permissible switch-on loss of the semiconductor switch is not exceeded as a result. In this way, it is possible, for example, to ensure that the overall balance of switch-on losses and switch-off losses is in each case kept as small as possible by avoiding the capacitor being switched on or off in a way that would be unfavorable with regard to a switch-on loss.

According to a third aspect of the present invention, a method for reducing switching losses of a semiconductor switch is provided. According to an example embodiment of the present invention, the method comprises: a first step for determining a current intensity of an electric current to be switched by means of the semiconductor switch and flowing along a load path of the semiconductor switch, while the semiconductor switch is in a switched-on state, a second step for closing an auxiliary switch, which is connected in a series circuit with a capacitor in parallel with the load path of the semiconductor switch, or for keeping the auxiliary switch in a closed state before a switch-off operation of the semiconductor switch if the determined current intensity exceeds a predefined current threshold value, or for opening the auxiliary switch or for keeping the auxiliary switch in an open state before a switch-off operation of the semiconductor switch if the determined current intensity does not exceed the predefined current threshold value. The features, combinations of features, and the advantages resulting therefrom correspond to those discussed in connection with the first-mentioned and second-mentioned aspects of the present invention, such that reference is made to the above statements in order to avoid repetitions.

### BRIEF DESCRIPTION OF THE DRAWINGS

In the following, exemplary embodiments of the present invention are described in detail with reference to the figures.

FIG. 1 shows an exemplary first embodiment of a circuit arrangement according to the present invention with a circuit unit according to an example embodiment of the present invention.

FIG. 2 shows a first exemplary embodiment of a partially integrated circuit unit according to the present invention.

FIG. 3 shows a second exemplary embodiment of a partially integrated circuit unit according to the present invention.

FIG. 4 shows an exemplary second embodiment of a circuit arrangement according to the present invention with two circuit units according to the present invention.

### DETAILED DESCRIPTION OF EXAMPLE EMBODIMENTS

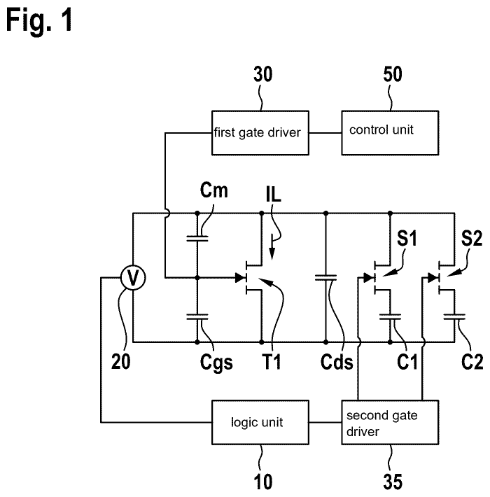

FIG. 1 shows an exemplary embodiment of a circuit arrangement according to the present invention with a circuit unit, wherein the circuit arrangement has a semiconductor switch T1 designed here as a HEMT, a first auxiliary switch S1 designed as a semiconductor switch, a second auxiliary switch S2 designed as a semiconductor switch, a first capacitor C1, a second capacitor C2, a logic unit 10, a control unit 50, a first gate driver 30, and a second gate driver 35. Furthermore, the parasitic capacitances Cm, Cgs, and Cds of the semiconductor switch T1 are shown.

A series circuit consisting of the first auxiliary switch S1 and the first capacitor C1 and a series circuit consisting of the second auxiliary switch S2 and the second capacitor C2 are each connected in parallel with a load path of the semiconductor switch T1.

The control unit 50 is configured to output control signals to the first gate driver 30 for switching on and off the semiconductor switch T1, on the basis of which control signals the gate driver 30 is configured to output corresponding gate voltages to a gate of the semiconductor switch T1.

The logic unit 10 is configured on the basis of a voltage measuring unit 20 to determine, in a switched-on state of the semiconductor switch T1, a current intensity IL of an electric current to be switched by means of the semiconductor switch T1 and flowing along the load path. For this purpose, the logic unit 10 has information about a characteristic map of the semiconductor switch T1 available, on the basis of which information the logic unit 10 is configured to convert measured voltage values across the load path into the currently present load current IL. The information about the characteristic map is stored, for example, in a memory unit (not shown), which is connected to the logic unit 10 by information technology.

On the basis of this configuration, the logic unit 10 is configured to close the first auxiliary switch S1 or to keep it in a closed state before a switch-off operation of the semiconductor switch T1 if the determined current intensity exceeds a predefined first current threshold value, and to open the first auxiliary switch S1 or to keep it in an open state before a switch-off operation of the semiconductor switch T1 if the determined current intensity does not exceed the predefined current threshold value.

The logic unit 10 is further configured to close the second auxiliary switch S2 or to keep it in a closed state before a switch-off operation of the semiconductor switch T1 if the determined current intensity exceeds a second predefined current threshold value, which is greater than the first current threshold value, and to open the second auxiliary switch S2 or to keep it in an open state before a switch-off operation of the semiconductor switch T1 if the determined current intensity does not exceed the second predefined current threshold value.

Preferably, at least the semiconductor switch T1, the first auxiliary switch S1, the second auxiliary switch S2, the first capacitor C1, and the second capacitor are monolithically or non-monolithically integrated.

It should be noted that the logic unit 10 may be connected to the control unit 50 by information technology in order, for example, to receive information about a switching state and/or future switching times of the semiconductor switch T1 from the control unit 50, which information can be used to determine suitable times for determining the load current IL to be switched.

Alternatively or additionally, the logic unit 10 may be configured to determine a present switching state of the semiconductor switch T1 on the basis of the voltage measurement by means of the voltage measuring unit 20.

It should also be noted that the logic unit 10 and/or the control unit 50 and/or the first gate driver 30 and/or the second gate driver 35 and/or the voltage measuring unit 20 can be integrated together into one or more components.

In a case in which currents which do not represent monotonically falling and/or rising load currents are to be switched by means of the circuit arrangement according to the present invention, the logic unit 10 is preferably configured to switch on and off the respective auxiliary switches S1, S2 on the basis of hystereses corresponding to the respective auxiliary switches S1, S2 in order to prevent undesired switching back and forth of the auxiliary switches S1, S2 due to non-monotonically rising or falling load currents.

On the basis of the circuit unit described in FIG. 1 or the higher-level circuit arrangement, a particularly low-loss switching operation for the semiconductor switch T1 can be realized by activating and deactivating the first capacitor C1 and the second capacitor C2 depending on a particular existing or expected load current.

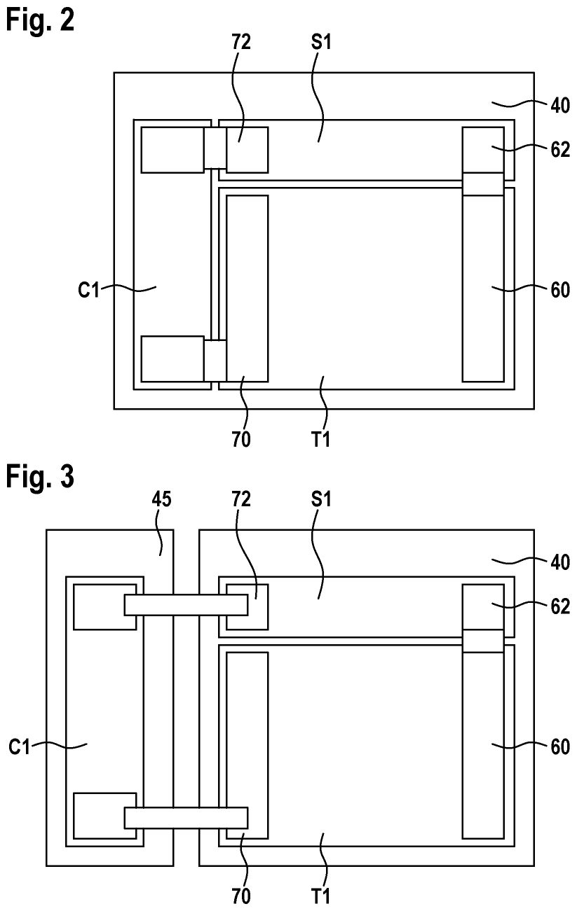

FIG. 2 shows a first exemplary embodiment of a partially integrated circuit unit according to the present invention.

In this embodiment, a semiconductor switch T1, an auxiliary switch S1, and a capacitor C1 are monolithically integrated on a single substrate 40. Accordingly, the drain terminals 60, 62 of the semiconductor switch T1 and of the auxiliary switch S1 are electrically connected to one another, while the respective source terminals 70, 72 of the semiconductor switch T1 and of the auxiliary switch S1 are connected to one another via the capacitor C1.

It should be noted that a logic unit (see FIG. 1) of the circuit arrangement according to the present invention may also be additionally integrated monolithically or non-monolithically with the components T1, S1, C1 described above.

FIG. 3 shows a second exemplary embodiment of a partially integrated circuit unit according to the present invention.

In this embodiment, a semiconductor switch T1 and an auxiliary switch S1 are monolithically integrated together on a first substrate 40, while a capacitor C1 is formed on a separate second substrate 45. The capacitor C1 is electrically connected, preferably in the form of a low-inductance connection, to the semiconductor switch T1 and the auxiliary switch S1, for example by means of bonding wires or by means of electrical conductors differing therefrom. The first substrate 40 and the second substrate 45 and the components T1, C1, C2 mounted thereon are preferably designed as a jointly encapsulated module.

It should be noted that a logic unit (see FIG. 1) of the circuit arrangement according to the present invention may also be additionally integrated monolithically or non-monolithically with the components T1, S1, C1 described above.

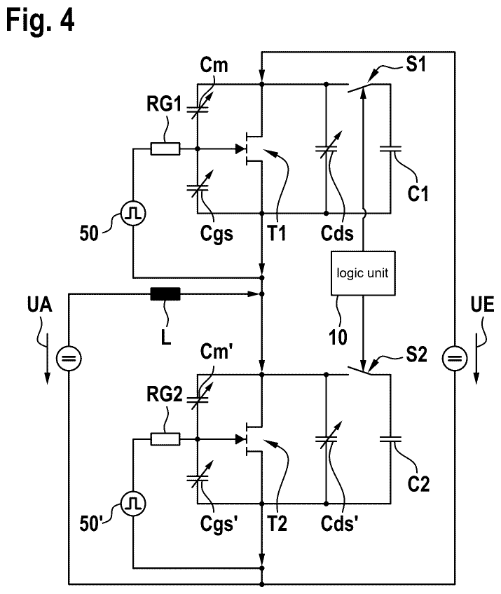

FIG. 4 shows a second embodiment of a circuit arrangement according to the present invention, designed as a buck converter, with two circuit units according to the present invention, in which buck converter an input voltage UE is converted into a desired output voltage UA by means of respective switches T1, T2 (here each designed as HEMT transistors) of a half-bridge of the circuit arrangement, a suitable control of the switches T1, T2 and an inductance L.

The suitable control of the switches T1, T2 is carried out via a first control unit 50 and a second control unit 50′ (which may be the same control unit), respective gate drivers (not shown) and respective gate resistors RG1, RG2.

The control units 50, 50′ are also configured to ensure that the switches T1, T2 are switched on substantially without voltage on the basis of a suitable switching scheme in order to keep switch-on losses of the switches T1, T2 as low as possible.

In addition, the parasitic capacitances Cm, Cgs, Cds, Cm′, Cgs′, and Cds′ of the two switches T1, T2 are shown. Parasitic inductances of the switches T1, T2 and of the circuit arrangement are not additionally shown here for reasons of clarity.

Since the components described above correspond to a buck converter from the related art, the specific functioning of the underlying buck converter is not discussed in order to avoid repetitions, and reference is made instead to the related art.

Deviating from the related art, the present circuit arrangement (i.e., the buck converter) is constructed on the basis of two circuit units according to the present invention, which are composed of a first auxiliary switch S1, a first capacitor C1, a second auxiliary switch S2, a second capacitor C2, and a logic unit 10.

The logic unit 10 is configured, on the basis of a connection (not shown) by information technology to the first control unit 50 and the second control unit 50′, to switch the respective auxiliary switches S1, S2 on and off independently of each other in order, according to the present invention, to reduce switch- off losses of the switches T1, T2 depending on the present load currents to be switched.

1-10. (canceled)

11. A circuit unit for reducing switching losses of a semiconductor switch, comprising:
the semiconductor switch;
an auxiliary switch;
a capacitor; and
a logic unit;
wherein:
a series circuit including the auxiliary switch and the capacitor is connected in parallel with a load path of the semiconductor switch, and
the logic unit is configured to:
determine, in a switched-on state of the semiconductor switch, a current intensity of an electric current to be switched using the semiconductor switch and flowing along the load path,
if the determined current intensity exceeds a predefined current threshold value, close the auxiliary switch or to keep the auxiliary switch in a closed state before a switch-off operation of the semiconductor switch, and
if the determined current intensity does not exceed the predefined current threshold value, open the auxiliary switch or to keep the auxiliary switch in an open state before a switch-off operation of the semiconductor switch.

12. The circuit unit according to claim 11, wherein:
(i) the semiconductor switch is: (a) a power transistor, and/or (b) a Si-, or SiC-, or GaN-based semiconductor switch, and/or (c) a MOSFET, or HEMT, or IGBT, or JFET, or FinFET, or CAVET, or a bipolar transistor, and/or
(ii) the auxiliary switch is a semiconductor switch and/or an electromechanical switch.

13. The circuit unit according to claim 11, wherein:
the current threshold value is an upper threshold value of a hysteresis and the logic unit is configured to switch the auxiliary switch from a closed state to an open state only when the value falls below a lower current threshold value of the hysteresis, which is smaller than the upper current threshold value, and/or
the circuit unit is configured to determine the current intensity of the current to be switched using the semiconductor switch, substantially immediately before a start of a switch-off operation of the semiconductor switch.

14. The circuit unit according to claim 11, wherein:
the capacitor is a first capacitor and the circuit unit includes at least a second capacitor,
the auxiliary switch is a first auxiliary switch and the circuit unit includes at least a second auxiliary switch,
the current threshold value is a first current threshold value,
a series circuit including the second auxiliary switch and the second capacitor is connected in parallel with the load path of the semiconductor switch, and
the logic unit is configured to:
if the determined current intensity exceeds a second predefined current threshold value, which is greater than the first current threshold value, close the second auxiliary switch or keep the second auxiliary switch in a closed state before a switch-off operation of the semiconductor switch, and
if the determined current intensity does not exceed the second predefined current threshold value, open the second auxiliary switch or keep the second auxiliary in an open state before a switch-off operation of the semiconductor switch.

15. The circuit unit according to claim 11, wherein the circuit unit is configured to determine the current intensity of the current to be switched using the semiconductor switch, based on:
a current measurement within the semiconductor switch, and/or
a voltage measurement across the load path of the semiconductor switch, and/or
information provided from outside, and/or
an operating state of the circuit unit, and/or
an operating state of a higher-level circuit arrangement containing the circuit unit.

16. The circuit unit according to claim 11, wherein:
the semiconductor switch and/or the auxiliary switch and/or the capacitor and/or the logic unit are monolithically integrated, and/or
a measuring unit configured to determine the current intensity of the current to be switched and/or a first driver circuit for controlling the semiconductor switch and/or a second driver circuit for controlling the auxiliary switch are monolithically integrated with the circuit unit.

17. The circuit unit according to claim 16, wherein:
at least the semiconductor switch and the auxiliary switch are formed on substrates which are electrically isolated from one another, and/or
the capacitor is connected to the circuit unit with low inductance.

18. A circuit arrangement, comprising:
at least one circuit unit for reducing switching losses of a semiconductor switch, the at least one circuit unit including:
the semiconductor switch;
an auxiliary switch;
a capacitor; and
a logic unit;
wherein:
a series circuit including the auxiliary switch and the capacitor is connected in parallel with a load path of the semiconductor switch, and the logic unit is configured to:
determine, in a switched-on state of the semiconductor switch, a current intensity of an electric current to be switched using the semiconductor switch and flowing along the load path,
if the determined current intensity exceeds a predefined current threshold value, close the auxiliary switch or to keep the auxiliary switch in a closed state before a switch-off operation of the semiconductor switch, and
if the determined current intensity does not exceed the predefined current threshold value, open the auxiliary switch or to keep the auxiliary switch in an open state before a switch-off operation of the semiconductor switch; and
a control unit configured to switch on the semiconductor switch of the at least one circuit unit substantially without voltage.

19. The circuit arrangement according to claim 18, wherein the circuit arrangement is configured to determine a switch-on loss of the semiconductor based on a present and/or an intended switching state of the auxiliary switch and to adjust the auxiliary switch in accordance with the determined current intensity when switching off the semiconductor switch, only when a predefined maximum permissible switch-on loss of the semiconductor switch is not exceeded as a result.

20. A method for reducing switching losses of a semiconductor switch, comprising the following steps:
determining a current intensity of an electric current to be switched using thje semiconductor switch and flowing along a load path of the semiconductor switch, while the semiconductor switch is in a switched-on state;
when the determined current intensity exceeds a predefined current threshold value, closing an auxiliary switch, which is connected in a series circuit with a capacitor in parallel with the load path of the semiconductor switch, or keep the auxiliary switch in a closed state before a switch-off operation of the semiconductor switch, and
when the determined current intensity does not exceed the predefined current threshold value, opening the auxiliary switch or keeping the auxiliary switch on an open state before a switch-off operation of the semiconductor switch.
